(19) United States
(12) Patent Application Publication
(10) Pub. No.: US 2007/0085130 A1
(43) Pub. Date: Apr. 19, 2007

(54) Tungsten-containing nanocrystal, an array thereof, a memory comprising such an array, and methods of making and operating the foregoing

(75) Inventor: Shih-Wei Wang, Hsin-Chu City (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/253,472

(22) Filed: Oct. 19, 2005

(51) Int. Cl. H01L 29/76

(52) U.S. Cl. 257/314

(57) ABSTRACT

A nanocrystal (or quantum dot) memory cell includes a tier of separated tungsten or tungsten-containing nanocrystals on an insulative tunneling layer. The nanocrystals are formed by low pressure chemical vapor deposition. The remainder of the cell may be fabricated pursuant to conventional MOS protocols. Generally, Fowler-Nordheim tunneling occurs during write and erase operations.

### TECHNICAL FIELD

Preferred embodiments of the present invention relate to a tungsten-containing nanocrystal or quantum dot, an array of such nanocrystals, a memory cell and a memory which include such an array, and to methods of making and operating the foregoing.

### BACKGROUND

EPROMs, EEPROMs, flash memories and other varieties of non-volatile memories fabricated pursuant to CMOS protocols are known. A memory cell in any of these memories generally is erased before being written. A major functional difference between an EPROM, on the one hand, and an EEPROM and a flash memory, on the other hand, is that the former is erased by exposure to a UV source and the latter are erased electrically. A major functional difference between an EEPROM and a flash memory is that all of the memory cells of the former, but not the latter, are electrically erased before a write operation is performed. In a flash memory, generally only one or more blocks of memory cells—not the entire memory—is erased prior to being written.

In the MOS arena, each memory cell of the above-described non-volatile memories typically includes a channel defined in a semiconductor substrate—either bulk or SOI—between a source and a drain formed in the substrate. A first, thin insulative layer is formed on the substrate overlying the channel region. Because the first insulative layer is typically an oxide through which electrons or holes may pass by “tunneling,” this layer is often called a “tunneling oxide,” although the term “tunneling layer” is used herein in contemplation of the use of insulative materials other than oxides.

A first continuous conductive layer, which functions as a floating electrode, is formed on the first insulative (or tunneling) layer and is overlaid with a second insulative layer functioning as a gate dielectric. A control or select electrode, comprising a second conductive layer, is formed on the second insulative layer.

The memory cells of all three types of non-volatile memories generally constitute floating gate CMOS field effect transistors in which the continuous floating electrode (the first conductive layer) is isolated from the control electrode (the second conductive layer) by the gate dielectric (the second insulative layer) and from the substrate by the first thin insulative (or tunneling) layer. This isolation permits the first conductive layer—the floating electrode—to store electrical charge. Generally, the first insulative layer of a flash memory and an EEPROM is much thinner—about 10 nm—than its counterpart in an EPROM. This thinness allows Fowler-Nordheim (“FN”) tunneling of electrons (or holes) through the first insulative layer to and from the floating electrode during write and erase operations. FN tunneling permits electrical erase of an entire memory (EEPROM) or of selected blocks thereof (flash memory).

The following discussion of EEPROM and flash memory cells assumes that the substrate is p-type and that the source and the drain are n-type. During a write operation of a memory cell in either type of memory, the floating electrode is negatively charged by hot carrier (electron) injection or by FN tunneling. It should be appreciated that the substrate may be n-type with a p-type source and drain, in which event the floating electrode is positively charged by hot carrier (hole) injection or via FN tunneling.

A write operation effected by hot electron injection involves grounding the substrate and the source, while applying a positive voltage (typically in the vicinity of about 12 volts) to the control electrode and a positive voltage (typically in the vicinity of about 6 volts) to the drain. An inversion region is formed in the channel and substantial current (electrons) flows from the source to the drain. The high current flow increases the kinetic energy of the electrons sufficiently so that some of them pass through the thin insulative (or tunneling) layer and collect on the floating electrode.

To perform a write operation by charging the floating electrode via FN tunneling, the source, drain and substrate are all grounded and a high positive voltage, typically about 15-20 volts, is applied to the control electrode. The high positive potential on the control electrode results in an attractive force on electrons in the source, substrate and drain, effecting FN tunneling of these electrons through the thin first insulative layer to collect on the floating electrode.

After either type of write operation, the negative charge on the floating electrode raises the threshold voltage above the voltage applied to the control electrode to perform a read operation. That is, when a positive read voltage is applied to the control electrode, the negative charge on the control floating electrode inhibits the formation of an inversion region in the channel, which, in turn, results in little or no current flowing from the source to the drain. Low or absent current flow is detected or read as a logical “0”.

During an erase operation performed on a cell of an EEPROM or flash memory, the negatively charged, continuous floating electrode is discharged by FN tunneling. Specifically, in a so-called high voltage source erase operation, a high positive voltage, typically about 12 volts, is applied to the source while the control electrode is grounded and the drain is unconnected. The large positive voltage of the source, as compared to the negative voltage on the floating electrode, attracts electrons from the floating gate. The electrons move to the source by FN tunneling through the thin tunneling layer (the first insulative layer).

An erase operation may also be effected by grounding the control electrode and applying a positive potential to the source, substrate and drain. Electrons on the floating electrode tunnel through the thin first insulative layer by FN tunneling and move into the source, substrate and drain.

After an erase operation, the lack of charge on the floating electrode lowers the threshold voltage of the cell below the read voltage applied to the control electrode. Accordingly, when a read voltage is applied to the control electrode of an erased cell, a high current flows from the source to the drain. High current flow is detected as a logical “1”.

It has been proposed to replace the continuous conductive layer comprising the floating electrode of EEPROM and flash memory cells with a tier of electrically floating, discontinuous charge storage elements made up of discrete nanocrystals or quantum dots. See “Nanocrystal Memory Cell Using High-Density Si_{0.73}Ge_{0.27} Quantum Dot Array,” by Chae, et al., Journal of the Korean Physical Society, Vol. 35, December 1999, pp. S995-S998 (“Chae”); “FinFET-A Self-Aligned Double-Gate MOSFET Scalable to 20 nm,” by Hisamoto, et al., IEEE Transactions of Electron Devices, Vol. 47, No. 12, December 2000, pp. 2320-2325 (“Hisamoto”); “Moto Lab Builds 4-bit ‘Nanocrystal’ Memory,” by David Lammers, EETimes, Mar. 31, 2003, (“Lammers”); “Metal Nanocrystal Memories-Part I: Device Design and Fabrication,” by Liu, et al, IEEE Transactions of Electron Devices, Vol. 49, No. 9, September, 2002, pp. 1606-1613 (“Liu”); and U.S. Pat. Nos. 6,159,620 to Heath, et al.(“Heath”), 6,307,782 to Sadd, et al. (“Sadd”), and 6,531,731 to Jones, et al. (“Jones”). These sources suggest that the nanocrystals may be constituted of SiGe (Chae, Sadd); Si (Lammers, Sadd and Jones); Ge (Sadd), Sn, and InAs; organically functionalized metals or metal alloys (Heath); and SiGeC and GaAs (Sadd).

The use of a tier of discrete, physically separated nanocrystals or quantum dots in place of a floating electrode embodied as a continuous conductive layer has been found to be advantageous for a number of reasons.

A localized or point defect in the tunneling layer of a memory cell having a continuous floating electrode constitutes a leakage path, or electrical short, between the floating electrode and the substrate. This leakage path permits the charge stored on the floating electrode during a write operation to dissipate leaving the cell in an erroneous erased state. To reduce such leakage, the tunneling layer adjacent a continuous floating electrode is relatively thick, typically on the order of about 8 nm or more.

If a tier of separated nanocrystals or quantum dots is used in place of the continuous floating electrode, the tunneling layer may be made relatively much thinner, on the order of about 4 nm or more, because a point defect can affect only a single crystal or dot. This leads to a memory cell having high reliability. The thin tunneling layer permits the nanocrystal memory cell to be operated (written and erased) at relatively lower power levels and at higher speeds. Moreover, the dimensions of a nanocrystal memory cell are smaller than those of a cell having a continuous floating electrode, so that more memory cells per unit substrate area may be fabricated.

Nanocrystal memory cells are capable of operating at room temperature, have long data retention times, and exhibit high cycling endurance. Further, nanocrystal memory cells are reported to be operable at plural, discrete threshold voltages due to Coulomb blockade effects resulting from electrons stored in the nanocrystals (Chae, Heath).

### SUMMARY OF THE INVENTION

Preferred embodiments of the present invention contemplate a nanocrystal or quantum dot memory cell in which the nanocrystals or dots are tungsten or contain tungsten. Preferably, the crystals or dots are self-assembled on a thin tunneling layer by low pressure chemical vapor deposition (“LPCVD”). In some embodiments, the dots are formed from silicon nanocrystals that effect selective reduction of tungsten. A memory comprising plural cells is also contemplated.

Preferred embodiments of the present invention contemplate a flash memory cell in which the continuous floating electrode is replaced with a tier of tungsten-containing nanocrystals which are charged and discharged by Fowler-Nordheim tunneling through an ultra thin insulative layer. Preferred embodiments of the present invention also contemplate a flash memory containing a plurality of such cells and methods of making the array, the cell and the memory.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a not-to-scale, sectioned front view of a nanocrystal memory cell in accordance with a preferred embodiment of the present invention;

FIG. 2 is an electrical schematic representation of the memory cell in FIG. 1;

FIGS. 3 and 4 are stylized representations, not to scale, of the memory cell of FIG. 1 during a write operation and an erase operation, respectively;

FIG. 5 is a schematic representation of the manner in which nanocrystals are deposited to fabricate the memory cell of FIG. 1; and

FIG. 6 includes energy band diagrams illustrating the operation of the memory cell hereof.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

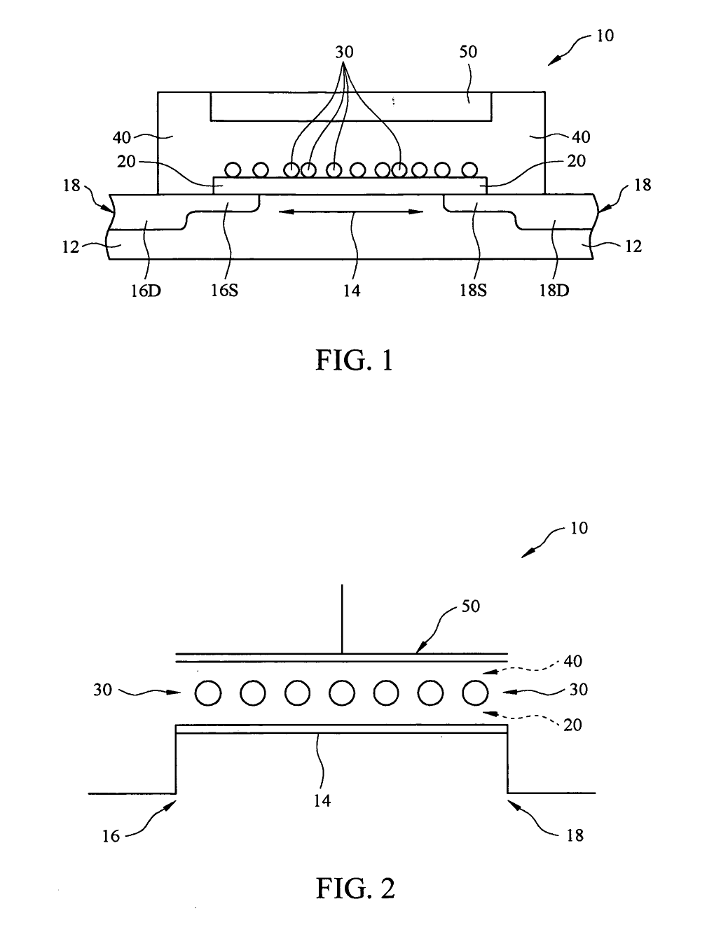

A preferred embodiment nanocrystal memory cell 10 is shown in FIG. 1. The cell 10 includes a semiconductor substrate 12 of n-type silicon, although p-type silicon and other n- and p-type semiconductors are contemplated. The substrate 12 may be a bulk semiconductor or a semiconductor layer on an insulative member (“SOI”).

A channel 14 is defined in the substrate 12 between an n-source 16 and an n-drain 18 formed by conventional methods. The source 16 and the drain 18 may comprise deep portions 16D and 18D and contiguous shallow extensions 16S and 18S. Spacers used during the formation of the source and drain 16 and 18 are not shown.

A thin tunneling layer 20 overlies the channel 14 and inner portions of the source and drain extensions 16S and 18S. The tunneling layer 20 is preferably silicon oxide formed by conventional lithography and has a thickness of about 3 nm to about 8 nm, although other materials—such as Si₃N₄, HfO₂, and Al₂O₃—and thicknesses are contemplated. The thickness of the tunneling layer 20 is preferably much less than that of typical tunneling layers used in continuous floating electrode memory cells.

Formed on the free surface of the tunneling layer 20 are a plurality of electrically floating, tungsten-containing nanocrystals or quantum dots 30. Preferably, the nanocrystals 30 are deposited and randomly distributed on the surface of the layer 20 as separated, discrete nanocrystals (islands or dots) by LPCVD. As set forth in greater detail below, the nanocrystals 30 self-assemble as they are deposited by LPCVD using WF₆ as a precursor gas and H₂, SiH₄, SiH₂Cl₂, Si₂H₆, GeH₄, or other gasses as reducing agents.

After the nanocrystals 30 have been deposited, a relatively thick insulative layer 40 is deposited by conventional photolithographic methods on the nanocrystals 30 and on portions of the free surface of the tunneling layer 20 not covered by nanocrystals 30. Preferably the insulative layer 40, which functions as a gate oxide, is silicon oxide and may have the same composition as the layer 20. Next, a conductive layer 50, which functions as a control or gate electrode is selectively deposited on the layer 40.

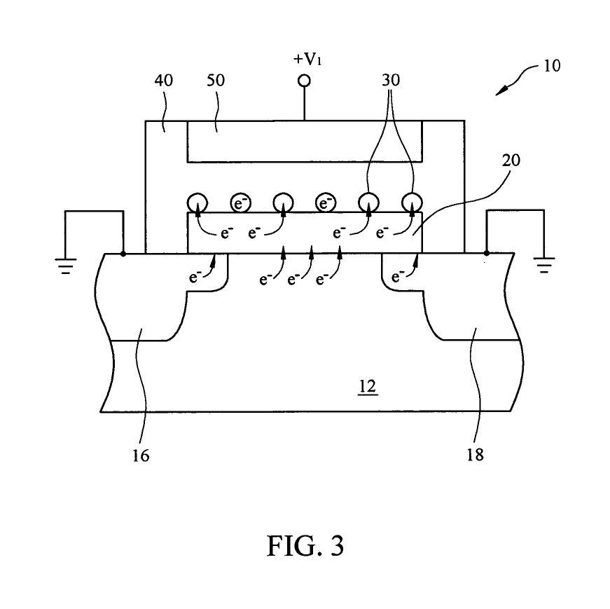

The nanocrystal memory cell 10 of FIG. 1 is schematically depicted in FIG. 2 in conformance with standard FET conventions. It should be noted that in none of the figures are the absolute or relative dimensions of the various elements accurately depicted. Dimensions have been exaggerated in order to clearly represent these elements.

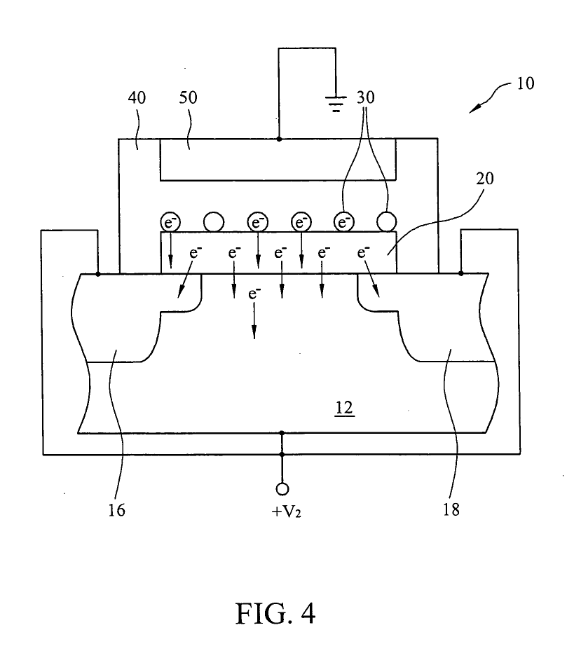

FIG. 3 illustrates the nanocrystal memory cell 10 during a write operation. The nanocrystal memory 10 generally is not written or programmed by hot electron injection because too much of the charge would be concentrated in the nanocrystals 30 closest to the drain 18. Accordingly, direct FN tunneling is effected to cause tunneling of electrons from the conduction band of the substrate 12 through the thin tunneling layer 20 to the conduction band of the nanocrystals 30. If the substrate is n-type, a negative potential on the control electrode 50 causes holes from the valence band of the substrate 12 to pass through the thin tunneling layer 20 to the valence band of the nanocrystals 30.

During a write operation, the source 16, drain 18 and substrate 12 may be grounded with a positive voltage +V1 applied to the control electrode 50. The resulting electric field effects a transfer of electrons e- from the substrate 12, source 16 and drain 18 through the thin tunneling layer 20 to the nanocrystals 30, as shown by the small arrows.

At the initiation of the write operation, the nanocrystals 30 are charged by electrons e- through random FN tunneling. However, the electrons e- tend to become evenly distributed in the tier of nanocrystals 30 due to Coulomb repulsion. The probability of FN tunneling by an electron to a particular nanocrystal 30 decreases during the write operation due to the repulsion fields of electrons stored in neighboring nanocrystals 30. Generally, the threshold voltage shift of the cell 10 saturates with respect to time until each nanocrystal 30 is charged with a single electron. Thereafter, additional electrons tunnel generally through the layer 20, until each nanocrystal 30 is charged with two electrons. This process generally continues until each nanocrystal is charged with the maximum number of electrons possible, given the architecture and geometry of the elements of the cell 10 and the magnitude of the voltage +V1.

The negative charge stored in the tier of nanocrystals 30 shifts (raises) the threshold voltage of the cell 10, as described earlier.

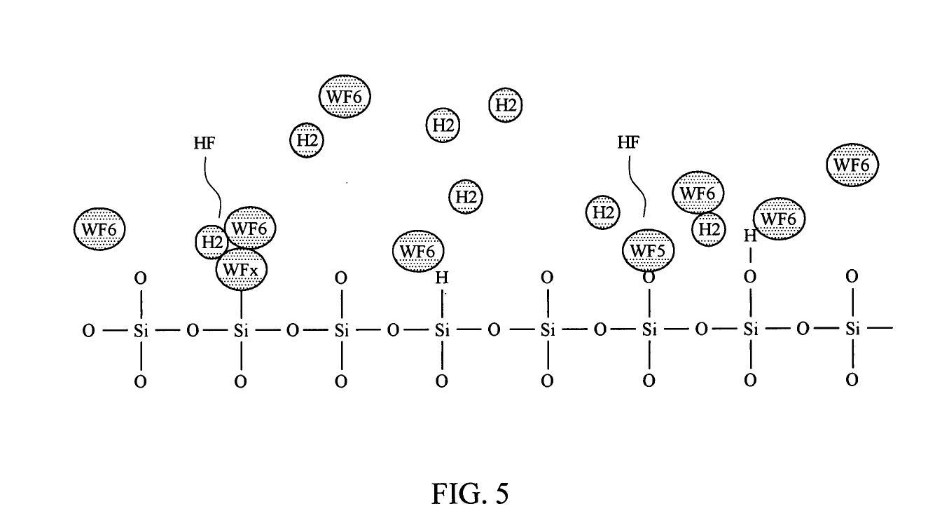

To erase the cell 10, as shown in FIG. 4, the control electrode 50 may be grounded as a positive voltage +V₂ is applied to the source 16, drain 18 and substrate 12. The field thereby effected moves the electrons e- stored in the nanocrystals 30 into the substrate 12, source 16 and drain 18 by FN tunneling through the thin layer 20, as shown by the small arrows. The discharge of the nanocrystals 30 shifts (lowers) the threshold voltage of the cell 10.

The fabrication of the cell 10 may be carried out pursuant to conventional MOS protocols, except for the formation of the tier of nanocrystals or quantum dots 30. As noted earlier, the separated nanocrystals are produced by self-assembly during LPCVD using WF₆ as a source gas and H₂ (which results in tungsten nanocrystals) or SiH₄ (which results in tungsten silicide nanocrystals) as a reduction gas. Reduction gases, such as SiH₄, SiH₂Cl₂, GeH₄, and Si₂H₆ are also contemplated. Diluents such as N₂ or Ar may be added to the other gases. Although the nanocrystals 30 are shown in FIGS. 1-4 as spherical, LPCVD carried out pursuant hereto typically results in the formation of separated nanocrystals 30 having generally hemispherical or partly spherical shapes, and diameters of about 3 nm to about 8 nm. The average spacing between neighboring nanocrystals 30 is about 5 nm or more, and the density of the nanocrystals 30 on the surface of the thin tunneling layer 20 is about 10¹¹ to about 10¹² cm⁻². The thickness of the thin tunneling layer 20 may range from about 3 nm to about 8 nm; as noted above, the layer 20 may be silicon oxide or other suitable material such as Si₃N₄, HfO₂, Al₂O₃ or combinations thereof.

During LPCVD, a pressure of about 3 millitorr to about 50 millitorr is maintained, and a temperature of about 250° C. to 400° C. is maintained. LPCVD is carried out for about 10 to about 200 seconds.

When WF₆ is used as the source gas and H₂ is used as the reduction gas, OH⁻ bonds resulting from water adsorbed by, or previous chemical treatment of, the SiO₂ surface initiate surface reactions with the WF₆ to reduce tungsten and induce nucleation thereof at random sites. In some embodiments, it may be preferable to treat the surface of the oxide with a hydrogen plasma or alternatively with a water rinse treatment in order to increase the number of dangling bonds (OH bonds or H bonds) that will serve as nucleation sites. Thereafter, separated, self-assembled nanocrystals of tungsten are grown at the sites according to:
[WF₆]_{gas}+3[H₂]_{gas}→[W]_{solid}+6[HF]_{gas}.
If WF₆ is used as the source gas and SiH₄ is used as the reduction gas, the OH⁻ bonds initiate surface reactions with the WF₆ and the monosilane to reduce tungsten silicide and induce nucleation thereof at random sites. Thereafter, separated, self-assembled nanocrystals of tungsten silicide are grown at the sites according to:
[WF₆]_{gas}+3[SiH₄]_{gas}→4[WSi]_{solid}+3[SiF₄]_{gas}+12[HF]_{gas}.

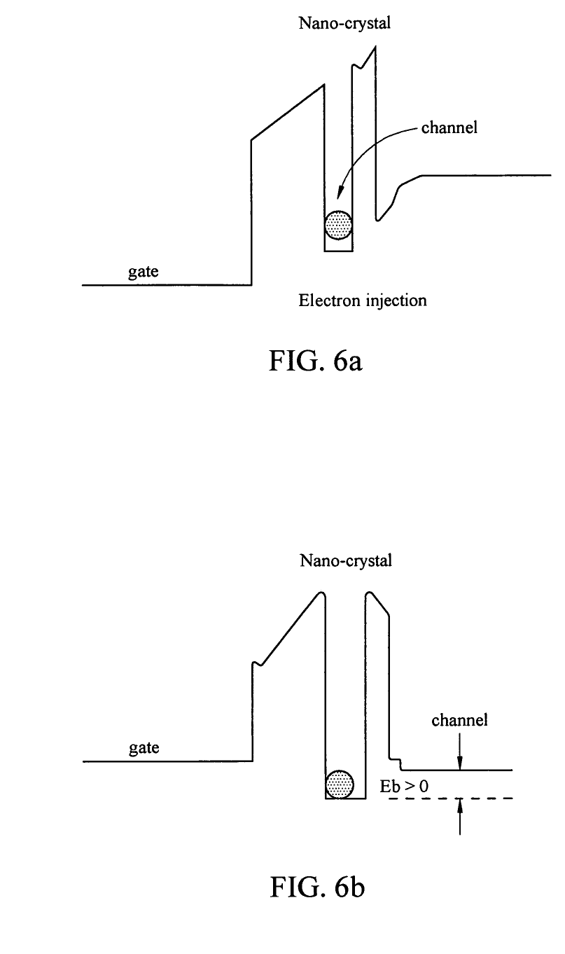

In general, and with reference to FIG. 5, if WF₆ and H₂ are used to produce the separated, self-assembled nanocrystals, each adsorbed OH⁻ will attract a WF₆ molecule. The H atom bonds with an F atom to form stable HF and volatile WF₅, i.e., OH⁻+WF₆→—OWF₅+HF↑, the WF₅ replacing the H atom and remaining on the SiO₂ surface. The WF₅ molecule then attracts H₂, one H atom of which bonds with an F atom, resulting in stable HF and volatile WF₄, i.e., H2+WF₅→—OWF₄+HF↑. The continuing reaction may be expressed as WFₓ+H→WFₓ₋₁+HF↑. Ultimately, the WFₓ species are reduced to W that nucleates at separate, self-assembled sites as the tungsten nanocrystals 30.

Those skilled in the art will appreciate that various parameters of LPCVD, such as time, pressure, temperature and the gasses used may be adjusted to obtain tungsten or tungsten-containing nanocrystals of selected sizes, spacings and densities.

In another embodiment, quantum dots may be formed by first forming a layer of silicon nanocrystal seeds. These seeds may be formed using conventional semiconductor deposition processes and are preferably formed to less than about 10 Å in diameter (again, the seeds may be spherical in shape, half spheres, or other shapes). Regardless of shape, these seeds serve as nucleation sites for the formation of Tungsten dots, as described above. These seeds effect selective reduction of tungsten and produce a gaseous moiety of SiFₓ.

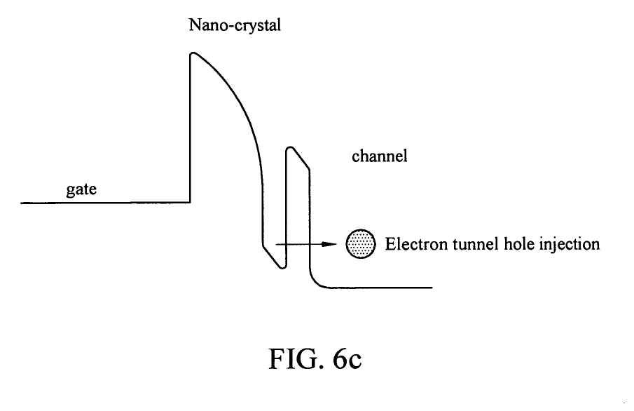

FIG. 6 illustrates the improved work function for a device using silicon nanocrystals. FIG. 6A illustrates the phenomenon of electron injunction whereby an electron from the channel region will tunnel through the floating gate dielectric into the nanocrystal, when the device is configured for a write operation, as described above. FIG. 6B illustrates that the energy band gap is greater than 0 for the tungsten nanocrystal, resulting in favorable storage (retention) performance. When the device is configured for an erase operation, such as described above, charge is able to migrate through the dielectric layer from the nanocrystal to the underlying channel region via electron tunneling and/or hole injection as shown in FIG. 6C.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, manufacture, composition of matter, means, methods and steps described in the specification. As one of ordinary skill in the art will readily appreciate from the disclosure of the present invention, processes, manufactures, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, manufactures, compositions of matter, means, methods, or steps.

What is claimed is:

1. An array of spaced tungsten-containing nanocrystals deposited as such on a surface by LPCVD.

2. An array as in claim 1, wherein the size of the nanocrystals is about 3 nm to about 8 nm and the spacing between neighboring nanocrystals is greater than about 5 nm.

3. An array as in claim 2, wherein the density of the nanocrystals is about 10¹¹ to about 10¹² cm⁻².

4. An array as in claim 1, wherein the surface is that of an insulative layer.

5. A memory cell comprising:
a substrate;
a first insulative layer formed on the substrate;
an layer of tungsten-containing nanocrystals formed on the first insulative layer;
a second insulative layer encapsulating and covering the nanocrystals; and
a conductive layer on the second insulative layer and overlying the array.

6. A memory cell as in claim 5, further comprising:
a channel region defined in the substrate between a source and a drain, the channel region underlying the first insulative layer and the layer of tungsten-containing nanocrystals.

7. The memory cell of claim 5 wherein the memory cell is a flash memory.

8. The memory cell of claim 5 wherein the nanocrystals are produced by LPCVD using a tungsten-containing source gas.

9. The memory cell of claim 8 wherein the source gas is WF₆.

10. The memory cell of claim 8, wherein LPCVD is effected at a pressure of about 3 millitorr to about 50 millitorr and at a temperature of about 250° C. to about 400° C. for about 10 seconds to about 200 seconds.

11. The memory cell of claim 8, wherein LPCVD is effected with H₂ as a reducing gas and the nanocrystals are tungsten.

12. The memory cell of claim 8, wherein LPCVD is effected with SiH₄ as a reducing gas and the nanocrystals are tungsten silicide.

13. A memory cell comprising:
a semiconductor substrate;
a source region and a drain region formed in or on the semiconductor substrate and defining a channel region therebetween in the substrate;
a tunneling layer substantially overlying the channel region;
a plurality of tungsten-containing quantum dots formed on the tunneling layer;
an insulative layer overlying and substantially insulating the quantum dots; and
a control gate substantially overlying the quantum dots and separated therefrom by the insulative layer.

14. The memory cell of claim 13 wherein the quantum dots have a major dimension of less than about 8 nm and the spacing between neighboring quantum dots is greater than about 5 nm.

15. The memory cell of claim 13 wherein the quantum dots have a density of about 10¹¹ to about 10¹² cm⁻².

16. The memory cell of claim 13 wherein the tunneling layer has a thickness of less than about 8 nm.

17. The memory cell of claim 13 wherein the tunneling layer is silicon oxide.

18. The memory cell of claim 13 wherein the insulative layer is silicon oxide.

19. The memory cell of claim 13 wherein the quantum dots comprise tungsten silicide.

20. The memory cell of claim 13 wherein the quantum dots are semi-spherical in shape.
